(19) United States
(12) Patent Application Publication
(10) Pub. No.: US 2025/0187044 A1
(43) Pub. Date: Jun. 12, 2025

(54) APPARATUS FOR TREATING SUBSTRATE

(71) Applicant: SEMES CO., LTD., Cheonan-si (KR)

(72) Inventors: Oh Yeol KWON, Cheonan-si (KR); Myung Chan CHO, Asan-si (KR); Hyun Hoo KIM, Cheonan-si (KR)

(73) Assignee: SEMES CO., LTD., Cheonan-si (KR)

(21) Appl. No.: 18/952,257

(22) Filed: Nov. 19, 2024

(30) Foreign Application Priority Data
Dec. 12, 2023 (KR) 10-2023-0179922

(51) Int. Cl. B08B 5/02; B08B 3/02; B08B 7/04; B08B 13/00

(52) U.S. Cl. CPC B08B 5/02; B08B 3/02; B08B 7/04; B08B 13/00

(57) ABSTRACT

Disclosed is an apparatus for treating a substrate, the apparatus including: a housing having an interior space; a treatment container disposed in the interior space and having a treatment space in which the substrate is treated; a support unit for supporting the substrate in the interior space; a nozzle unit having a nozzle for supplying a treatment liquid to the substrate supported on the support unit; an exhaust unit for exhausting airflow in the treatment space; an airflow supply unit for providing downdraft airflow into the interior space; and an inspection module for inspecting the treatment space, in which the inspection module is installed in the airflow supply unit.

### CROSS-REFERENCE TO RELATED APPLICATIONS

This application claims priority to and the benefit of Korean Patent Application No. 10-2023-0179922 filed in the Korean Intellectual Property Office on Dec. 12, 2023, the entire contents of which are incorporated herein by reference.

### TECHNICAL FIELD

The present invention relates to an apparatus for treating a substrate, and more particularly to an apparatus for treating a substrate while supplying downdraft airflow into an interior space of a housing.

### BACKGROUND ART

To manufacture semiconductor devices, various processes are performed, such as photography, deposition, ashing, etching, and ion implantation. In addition, before and after these processes are performed, a cleaning process of cleaning particles remaining on the substrate is performed. In the cleaning process of the substrate, the substrate treatment process is performed with various treatment liquids.

To manufacture semiconductor devices, various processes are performed, such as photography, deposition, ashing, etching, and ion implantation. In addition, before and after these processes are performed, a cleaning process of cleaning particles remaining on the substrate is performed. In the cleaning process of the substrate, the substrate treatment process is performed with various treatment liquids.

The cleaning process includes a process for supplying a chemical to a substrate that is supported on a spin head and rotates, a process of removing the chemical from the substrate by supplying a cleaning solution, such as deionized water (DIW), to the substrate, a process of supplying an organic solvent, such as an isopropyl alcohol (IPA) liquid, having lower surface tension than the cleaning solution, to the substrate to substitute the cleaning solution on the substrate with the organic solvent, and a process of removing the substituted organic solvent from the substrate.

FIG. 1 is a cross-sectional view of a typical substrate treating apparatus. Referring to FIG. 1, a substrate treating apparatus 1000 is provided with a treatment container 1200 surrounding a support unit 1100 that supports a substrate inside a housing, and is provided to treat the substrate while supplying a liquid to the rotating substrate. During the treatment of the substrate, a fan filter unit 1300 for providing downdraft airflow into an interior space of the housing to facilitate exhausting gas generated during the substrate treatment, and a photographing module 1400 for photographing the interior of the housing are provided. Here, the fan filter unit 1300 and the photographing module 1400 are separately installed.

When the fan filter unit 1300 and the photographing module 1400 are provided as separate installations, the sagging of the intermediate distance structure may cause lift, which may cause scattering to penetrate the interior of the housing, and a separate power source is required.

Furthermore, the photographing module 1400 has no introduced airflow, causing airflow stagnation zones in the interior space of the housing provided below the photographing module 1400.

### SUMMARY OF THE INVENTION

The present invention has been made in an effort to provide a substrate treating apparatus capable of eliminating airflow stagnation caused by downdraft airflow in an interior space of a housing when treating a substrate while providing downdraft airflow in the interior space of the housing.

The present invention has also been made in an effort to provide a substrate treating apparatus which, when treating a substrate while providing downdraft airflow in an interior space of the housing, prevents scattering from penetrating the interior of the housing.

The problem to be solved by the present invention is not limited to the above-mentioned problems, and the problems not mentioned will be clearly understood by those skilled in the art from the descriptions below.

An exemplary embodiment of the present invention provides an apparatus for treating a substrate, the apparatus including: a housing having an interior space; a treatment container disposed in the interior space and having a treatment space in which the substrate is treated; a support unit for supporting the substrate in the interior space; a nozzle unit having a nozzle for supplying a treatment liquid to the substrate supported on the support unit; an exhaust unit for exhausting airflow in the treatment space; an airflow supply unit for providing downdraft airflow into the interior space; and an inspection module for inspecting the treatment space, in which the inspection module is installed in the airflow supply unit.

In the exemplary embodiment, the airflow supply unit may include: a first frame having a first airflow introduction space formed therein; and a first filter installed on a bottom wall of the first frame, and the inspection module may include a second frame provided to protrude from a bottom surface of the first frame in a downward direction of the first frame, and having a second airflow introduction space formed therein.

In the exemplary embodiment, the inspection module may further include a camera mounted in the second airflow introduction space and provided to photograph the treatment space.

In the exemplary embodiment, the camera may be a thermal imaging camera.

In the exemplary embodiment, the first airflow introduction space and the second airflow introduction space may be provided so that a portion of the airflow in the first airflow introduction space is introduced into the second airflow introduction space.

In the exemplary embodiment, the second frame may include an outer wall, an inner wall, and a bottom wall, the second airflow introduction space may be defined by walls including the outer wall, the inner wall, and the bottom wall, the inner wall may be a wall facing the treatment space, and the bottom wall may have an outlet hole formed for the airflow introduced into the second airflow introduction space to flow in a downward direction.

In the exemplary embodiment, the bottom wall may be equipped with a second filter.

In the exemplary embodiment, the inner wall may be provided as a window to allow the inspection module to photograph.

In the exemplary embodiment, the inner wall may be provided with an inclined surface that approaches a lateral wall of the housing as it descends.

In the exemplary embodiment, an outer side of the treatment container in the interior space may be provided with a waiting port in which the nozzle waits, and when the interior space is separated into an area in which the treatment container is provided and an area in which the waiting port is provided based on a line perpendicular to a direction in which the treatment container and the waiting port are arranged when viewed from above, the inspection module may be disposed in the area in which the waiting port is provided.

In the exemplary embodiment, the first frame and the second frame may be integrally provided.

In the exemplary embodiment, a fan may be installed on a top wall of the first frame.

Another exemplary embodiment of the present invention provides an apparatus for treating a substrate, the apparatus including: a housing having an interior space; a first frame having a first airflow introduction space into which gas from the outside is introduced; and a second frame positioned on a bottom wall of the first frame so as to protrude downwardly from the first frame, and having a second airflow introduction space therein, in which a portion of the airflow introduced into the first airflow introduction space flows through the bottom wall of the first frame into the interior space, another portion of the airflow introduced into the first airflow introduction space flows from the first airflow introduction space to the second airflow introduction space, and then flows through a bottom wall of the second frame into the interior space, and the second airflow introduction space is equipped with a camera.

In the exemplary embodiment, a fan may be installed on a top wall of the first frame.

In the exemplary embodiment, the bottom wall of the first frame may be mounted with a first filter.

In the exemplary embodiment, the bottom wall of the second frame may be mounted with a second filter.

In the exemplary embodiment, the camera may be a thermal imaging camera.

Still another exemplary embodiment of the present invention provides an apparatus for treating a substrate, the apparatus including: a housing having an interior space; a treatment container disposed in the interior space and having a treatment space in which the substrate is treated; a support unit for supporting the substrate in the treatment space; a nozzle unit having a nozzle for supplying a treatment liquid to the substrate supported on the support unit; an exhaust unit for exhausting airflow in the treatment space; an airflow supply unit for providing downdraft airflow into the interior space; and an inspection module for inspecting the interior space, in which the airflow supply unit includes: a first frame having a first airflow introduction space formed therein; a first filter installed in an upper portion of the first frame; and a first fan installed in a lower portion of the first frame, and the inspection module includes: a second frame installed in the first frame and having a second airflow introduction space communicating with the first airflow introduction space; a camera provided in the second airflow introduction space; and a second filter installed on a bottom wall of the second frame, and airflow introduced into the second airflow introduction space flows through the second filter into the interior space.

In the exemplary embodiment, the second frame may include an outer wall, an inner wall, and a bottom wall, the second airflow introduction space may be defined by walls including the outer wall, the inner wall, and the bottom wall, the inner wall may be a wall facing the treatment space, and an outlet hole may be formed in the bottom wall such that airflow introduced into the second airflow introduction space flows in a downward direction, the inner wall may be provided as a window to allow the camera to photograph, and the inner wall may be provided with an inclined surface that approaches a lateral wall of the housing as it descends.

In the exemplary embodiment, an outer side of the treatment container in the interior space may be provided with a waiting port in which the nozzle waits, and when the interior space is separated into an area in which the treatment container is provided and an area in which the waiting port is provided based on a line perpendicular to a direction in which the treatment container and the waiting port are arranged when viewed from above, the inspection module may be disposed in the area in which the waiting port is provided.

According to the exemplary embodiment of the invention, the first frame including the fan and the filter and the second frame including the inspection module may be integrally provided to prevent scattering from penetrating the interior space of the housing.

According to the exemplary embodiment of the invention, the first frame including the fan and the filter and the second frame including the inspection module may be integrally provided, thereby eliminating the need for a separate power source for the inspection module.

According to the exemplary embodiment of the invention, by installing an additional filter below the inspection module, airflow stagnation zones may not occur in the interior space of the housing.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a cross-sectional view schematically illustrating a process chamber of a typical substrate treating apparatus.

FIG. 2 is a top plan view schematically illustrating a substrate treating apparatus according to an exemplary embodiment of the present invention.

FIG. 3 is a diagram schematically illustrating an exemplary embodiment of the process chamber of the substrate treating apparatus of FIG. 2.

FIG. 4 is a bottom view of an airflow supply unit according to the exemplary embodiment of the present invention.

FIGS. 5 to 6 are diagrams illustrating the effect of the substrate treating apparatus according to the exemplary embodiment of the present invention.

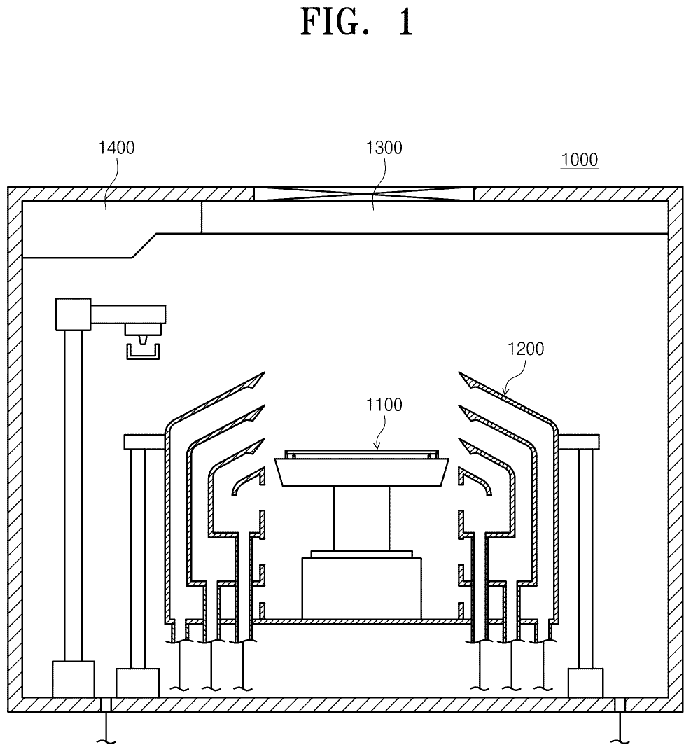

### DETAILED DESCRIPTION

Hereinafter, an exemplary embodiment of the present invention will be described in more detail with reference to the accompanying drawings. An exemplary embodiment of the present invention may be modified in various forms, and the scope of the present invention should not be construed as being limited by the exemplary embodiment described below. The present exemplary embodiment is provided to more completely explain the present invention to those skilled in the art. Therefore, the shapes of components in the drawings are exaggerated to emphasize a clearer description.

In the present exemplary embodiment, a process of treating a substrate with a liquid by supplying the liquid, such as a cleaning solution, onto the substrate is described as an example. However, the present exemplary embodiment is not limited to the cleaning process, and may be applied to various processes, such as an etching process, an ashing process, and a developing process, of treating a substrate by using a treatment liquid.

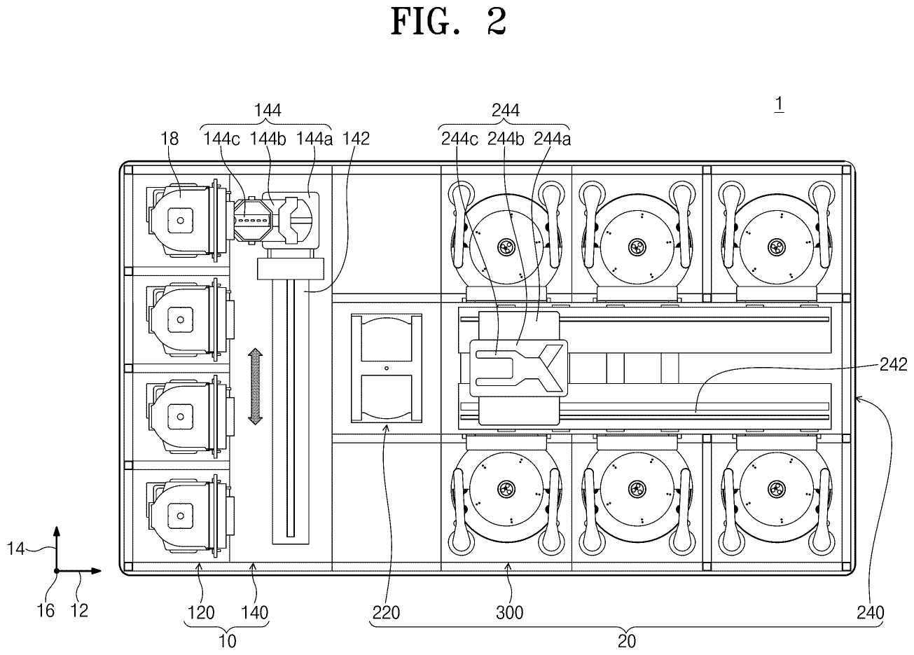

Hereinafter, one example of the present invention will be described in detail with reference to FIGS. 2 to 6.

FIG. 2 is a top plan view schematically illustrating a substrate treating apparatus according to an exemplary embodiment of the present invention.

Referring to FIG. 2, the substrate treating apparatus 1 includes an index module 10 and a process treating module 20. The Index module 10 includes a load port 120 and a transfer frame 140. The load port 120, the transfer frame 140, and the process treating module 20 are arranged in a sequential row. Hereinafter, a direction in which the load port 120, the transfer frame 140, and the process treating module 20 are arranged is referred to as a first direction 12, a direction perpendicular to the first direction 12 when viewed from above is referred to as a second direction 14, and a direction perpendicular to a plane including the first direction 12 and the second direction 14 is referred to as a third direction 16.

A container 130 in which a substrate W is accommodated is seated on the load port 120. A plurality of load ports 120 may be provided, and the plurality of load ports 120 may be disposed in series in the second direction 14. The number of load ports 120 may be increased or decreased depending on process efficiency and footprint requirements of the process treating module 20. The container 130 is formed with a plurality of slots (not illustrated) for receiving the substrates W in a horizontal position relative to the ground. As the container 130, a Front Opening Unified Pod (FOUP) is used.

The process treating module 20 includes a buffer unit 220, a transfer chamber 240, and a process chamber 300. The transfer chamber 240 may disposed so that a longitudinal direction thereof is parallel to the first direction. On opposite sides of the transfer chamber 240, the process chambers 300 are disposed, respectively. On one side and the other side of the transfer chamber 240, the process chambers 300 are provided to be symmetrical with respect to the transfer chamber 240. On one side of the transfer chamber 240, a plurality of process chambers 300 is provided. Some of the process chambers 300 are disposed along the longitudinal direction of the transfer chamber 240. Further, some of the process chambers 300 are disposed stacked on top of each other. That is, the process chambers 260 may be disposed in an arrangement of A×B at one side of the transfer chamber 240. Herein, A is the number of process chambers 300 provided in series in the first direction 12, and B is the number of process chambers 300 provided in series in the third direction 16. When four or six process chambers 300 are provided at one side of the transfer chamber 240, the process chambers 260 may be disposed in an arrangement of 2×2 or 3×2. The number of process chambers 260 and 280 may be increased or decreased. Unlike the description above, the process chamber 300 is provided on only one side of the transfer chamber 240. Further, the process chamber 300 is provided in a single layer on one side and opposite sides of the transfer chamber 240.

The buffer unit 220 is disposed between the transfer frame 140 and the transfer chamber 240. The buffer unit 220 provides a space for the substrate W to stay between the transfer chamber 240 and the transfer frame 140 before the substrate W is transferred. Slots (not illustrated) on which the substrate W is placed is provided inside the buffer unit 220. The plurality of slots (not illustrated) is provided so as to be spaced apart from each other in the third direction 16. In the buffer unit 220, the side facing the transfer frame 140 and the side facing the transfer chamber 240 are open.

The transfer frame 140 transfers the substrate W between the container 130 seated in the load port 120 and the buffer unit 220. The transfer frame 140 is provided with an index rail 142 and an index robot 144. The index rail 142 is provided so that a longitudinal direction thereof is parallel to the second direction 14. The index robot 144 is installed on the index rail 142, and linearly moves in the second direction 14 along the index rail 142. The index robot 144 includes a base 144a, a body 144b, and an index arm 144c. The base 144a is installed to be movable along the index rail 142. The body 144b is coupled to the base 144a. The body 144b is provided to be movable in the third direction 16 on the base 144a. Further, the body 144b is provided to be rotatable on the base 144a. The index arm 144c is coupled to the body 144b and is provided to be movable forwardly and backwardly with respect to the body 144b. A plurality of index arms 144c is provided to be individually driven. The index arms 144c are disposed to be stacked in the state of being spaced apart from each other in the third direction 16. Some of the index arms 144c may be used when the substrate W is transferred from the process treating module 20 to the container 130, and another some of the plurality of index arms 144c may be used when the substrate W is transferred from the container 130 to the process treating module 20. This prevents particles generated from the substrate W before the process treatment from adhering to the substrate W after the process treatment in the process of loading and unloading by the index robot 144, the substrate W.

The transfer chamber 240 transfers the substrate W between the buffer unit 220 and the process chamber 300 and between the process chambers 300. The transfer chamber 240 is provided with a guide rail 242 and a main robot 244. The guide rail 242 is disposed so that a longitudinal direction thereof is parallel to the first direction 12. The main robot 244 is installed on the guide rail 242, and linearly moves on the guide rail 242 in the first direction 12. The main robot 244 includes a base 244a, a body 244b, and a main arm 244c. The base 244a is installed to be movable along the guide rail 242. The body 244b is coupled to the base 244a. The body 244b is provided to be movable in the third direction 16 on the base 244a. Further, the body 244b is provided to be rotatable on the base 244a. The main arm 244c is coupled to the body 244b, and provided to be movable forwardly and backwardly with respect to the body 244b. A plurality of main arms 244c is provided to be individually driven. The main arms 244 are disposed to be stacked in the state of being spaced apart from each other in the third direction 16.

The process chamber 300 may be a liquid treatment chamber that supplies liquid to the substrate W to perform a liquid treatment process. For example, the liquid treating process may be a cleaning process of cleaning the substrate with a cleaning liquid. A chemical treatment, a rinse treatment, and a drying treatment are all performed on the substrate within the process chamber. Optionally, a drying chamber for drying the substrate is provided separately from the liquid treatment chamber.

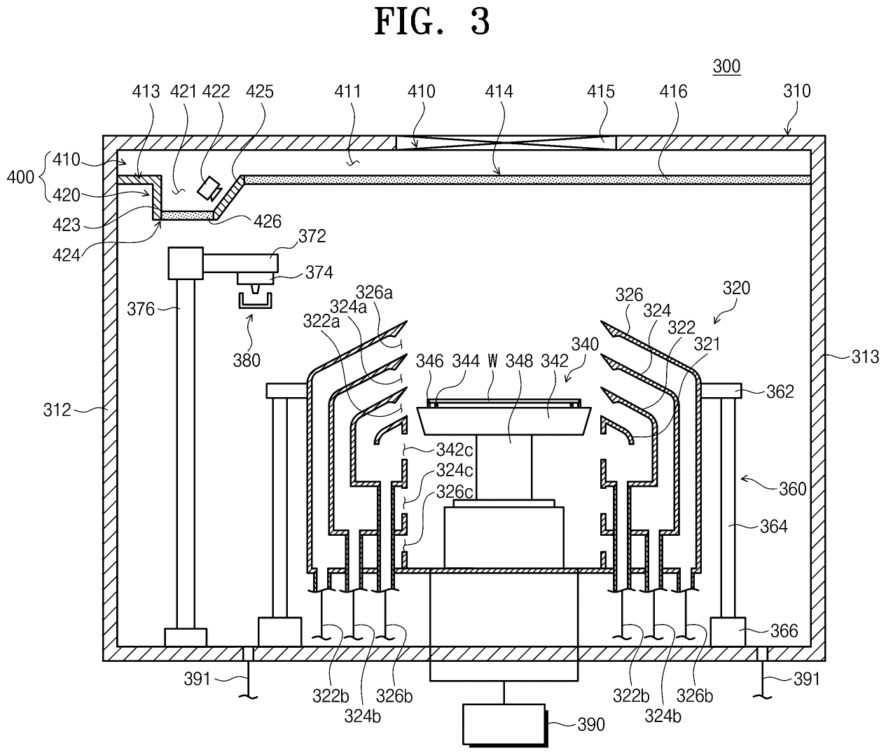

FIG. 3 is a diagram schematically illustrating an exemplary embodiment of the process chamber of FIG. 2.

Referring to FIG. 3, the process chamber 300 includes a housing 310, a treatment container 320, a substrate support unit 340, a nozzle unit 370, an exhaust unit 390, and an airflow supply unit 400.

The housing 310 forms a space inside. The housing 310 has a top wall 311, a bottom wall, and lateral walls. In one example, the housing has a substantially cuboidal shape, and the lateral walls of the housing have a first lateral wall 312 and a second lateral wall 313. The first sidewall 312 is positioned opposite the second sidewall 313.

The treatment container 320 is located inside the housing 310. The treatment container 320 has a treatment space for treating the substrate W. The treatment container 320 has includes a guide wall 321, an inner recovery container 322, an intermediate recovery container 324, and an outer recovery container 326. Each of the recovery containers 322, 324, and 326 separately recovers a different treatment liquid from the treatment liquids used in the process. The guide wall 321 is provided in the shape of an annular ring surrounding the substrate support unit 340, and the inner recovery container 322 is provided in the shape of an annular ring surrounding the guide wall 321. The intermediate recovery container 324 is provided in the shape of an annular ring surrounding the inner recovery container 322, and the outer recovery container 326 is provided in the shape of an annular ring surrounding the intermediate recovery container 324. A space 322a between the inner recovery container 322 and the guide wall 321 functions as a first inlet through which the treatment liquid is introduced. A space 324a between the inner recovery container 322 and the intermediate recovery container 324 functions as a second inlet through which the treatment liquid is introduced. A space 326a between the intermediate recovery container 324 and the outer recovery container 326 functions as a third inlet through which the treatment liquid is introduced. In addition, a space 322c between the bottom end of the guide wall 321 and the inner recovery container 322 functions as a first outlet through which the fume and airflow generated from the treatment liquid are discharged. A space 324c between the bottom end of the inner recovery container 322 and the intermediate recovery container 324 functions as a second outlet through which the fume and airflow generated from the treatment liquid are discharged. A space 326c between the bottom end of the intermediate recovery container 324 and the outer recovery container 326 functions as a third outlet through which the fume and airflow generated from the treatment liquid are discharged. Each recovery container receives a different type of treatment liquid. The recovery containers 322, 324, and 326 are connected with circulation lines 322b, 324b, and 326b, respectively, to extend vertically in the down direction from the bottom surface. Each of the recovery lines 322b, 324b, and 326b discharges the treatment liquid, fume, and airflow introduced through the respective recovery containers 322, 324, and 326. The discharged treatment liquid is reused via an external treatment liquid regeneration system (not illustrated).

The substrate support unit 340 supports the substrate W and rotates the substrate W during the process progress. The substrate support unit 340 includes a body 342, a support pin 344, a chuck pin 346, a support shaft 348, and a driver (not illustrated). The body 342 has a top surface that is substantially circular when viewed from above. The support shaft 348 is fixedly coupled to the lower surface of the body 342, and the support shaft 348 is provided to be rotatable by the driver 349.

A plurality of support pins 344 is provided. The support pins 344 are spaced apart at the edge of an upper surface of the body 342 at predetermined intervals and protrude upwardly from the body 342. The support pins 344 are arranged to have an annular ring shape as a whole by combination with each other. The support pin 344 supports an edge of the rear surface of the substrate W so that the substrate W is spaced apart from the upper surface of the body 342 at a predetermined distance.

A plurality of chuck pins 346 is provided. The chuck pin 346 is disposed further from the center of the body 342 than the support pin 344. The chuck pin 346 is provided to protrude upwardly from the body 342. The chuck pin 346 supports the lateral portion of the substrate W so that the substrate W is not laterally separated from the original position when the substrate W is rotated. The chuck pin 346 is provided for linear movement along the radial direction of the body 342 between a waiting position and a support position. The waiting position is a position farther from the center of the body 342 relative to the support position. When the substrate W is being loaded to or unloaded from the substrate support unit 340, the chuck pin 346 is positioned in the waiting position, and when performing a process on the substrate W, the chuck pin 346 is positioned in the support position. At the support position, the chuck pin 346 is in contact with the lateral portion of the substrate W.

The lifting unit 360 linearly moves the treatment container 320 in the up and down direction. As the treatment container 320 is moved up and down, the relative height of the treatment container 320 with respect to the spin head of the substrate support unit 340 changes. The lifting unit 360 includes a bracket 362, a travel shaft 364, and a driver 366. The bracket 362 is fixedly installed on the outer wall of the treatment container 320, and a moving shaft 364, which is moved in the vertical direction by the driver 366, is fixedly coupled to the bracket 362. The treatment container 320 is lowered such that the spin head of the substrate support unit 340 protrudes over the top of the treatment container 320 when the substrate W is placed on the spin head of the substrate support nit 340 or lifted from the spin head of the substrate support unit 340. In addition, when the process is in progress, the height of the treatment container 320 is adjusted so that the treatment liquid flows into the preset recovery container according to the type of treatment liquid supplied to the substrate W. Optionally, the lifting unit 360 may move the spin head of the substrate support unit 340 in an upward or downward direction.

The nozzle unit 370 supplies the treatment liquid onto the substrate W. The nozzle unit 370 may be provided in a plurality, each supplying a different type of treatment liquid.

The nozzle unit 370 includes a support shaft 376, an arm 372, a driver 378, and a nozzle 374. The support shaft 376 is located on one side of the treatment container 320. The support shaft 376 has the shape of a rod with its longitudinal direction facing the third direction. The support shaft 376 is provided to be rotatable by the driver 378. The arm 372 is coupled to the upper end of the support shaft 376. The arm 372 extends perpendicularly from support shaft 376. At the end of the arm 372, the nozzle 374 is fixedly coupled. As the support shaft 376 is rotated, the nozzle 374 is swing moveable with the arm 372. The nozzle 374 is swing moved to the process position and the waiting position. Herein, the process position is a position where the nozzle 374 faces the substrate W supported by the substrate support unit 340, and the waiting position is a position where the nozzle 374 is output of the process position.

Optionally, the arm 372 is provided to be movable forwardly and backwardly along its longitudinal direction. When viewed from the top, the nozzle 374 is swing moveable to align with the center axis of the substrate W.

The treatment liquid may be any one of a chemical, a rinse liquid, and an organic solvent. The chemical includes nitric acid, phosphoric acid, or sulfuric acid. The rinse liquid includes water. An organic solvent includes an alcohol, such as isopropyl alcohol.

The waiting port 380 may provide a waiting space for the nozzle 374 to wait. The nozzle 374 may be positioned in the waiting position, i.e., the upper side of the waiting port 380, when the process is not in progress. The waiting port 380 may function as a liquid receptacle to receive a pre-discharged treatment liquid before the nozzle 374 begins the process on the substrate W. Additionally, the waiting port 380 may function as a liquid receptacle to receive treatment liquid that collects at the end of the nozzle 374 while the nozzle 374 is waiting.

The exhaust unit 390 exhausts fumes and gas generated in the treatment space. The exhaust unit 390 exhausts fumes and gas generated during liquid treatment of the substrate. The exhaust unit 390 is coupled to the bottom surface of the treatment container 320.

The exhaust duct 391 exhausts fumes and airflow generated in the interior space of housing 310. Exhaust duct 391 exhausts fumes and airflow from the treatment space during liquid treatment of the substrate. The exhaust duct 391 is coupled to the bottom wall of the housing 310.

During the liquid treatment of the substrate, the fumes and airflow are exhausted only through the exhaust unit 390 between the exhaust unit 390 and the exhaust duct 391. Optionally, fumes and gases are exhausted simultaneously through the exhaust unit 390 and the exhaust duct 391 during the liquid treatment of the substrate. In this case, the exhaust duct 391 evacuates a smaller volume than the exhaust unit 390 by setting the exhaust pressure during the liquid treatment of the substrate to be lower than the exhaust pressure of the exhaust unit 390. This prevents the fume generated in the treatment space from flowing back outside the treatment space.

The airflow supply unit 400 provides downdraft airflow to the interior space of the housing 310.

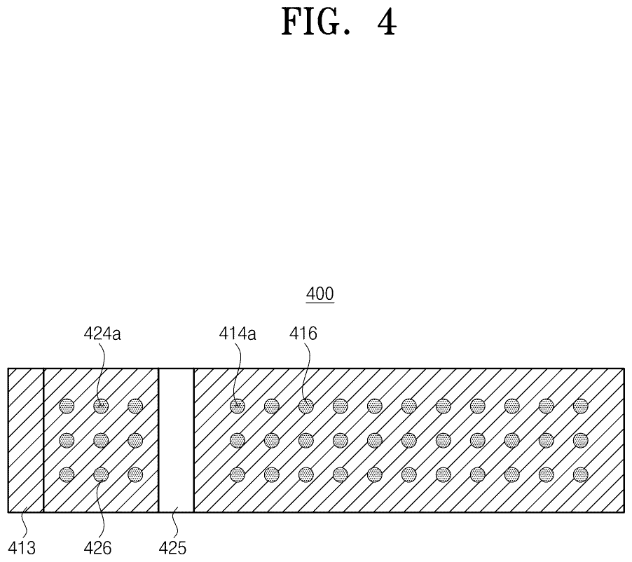

FIG. 4 is a bottom view of the airflow supply unit according to the exemplary embodiment of the present invention.

Referring now to FIG. 4 in addition to FIG. 3, the airflow supply unit 400 will be described.

The airflow supply unit 400 is installed in an upper portion of the interior space of the housing 310. The airflow supply unit 400 includes a first frame 410 and a second frame 420. The first frame 410 and the second frame 420 may be integrally constructed. Optionally, the first and second frames may be fabricated separately, and the second frame may be fixedly coupled to the first frame.

The first frame 410 is provided on top of the airflow supply unit 400. A first airflow introduction space 411 is formed in an inner space of the first frame 410. The first frame 410 includes a top wall 412, a first bottom wall 413, and a second bottom wall 414.

The top wall 412 of the first frame 410 is provided on the top wall 311 of the housing 310. A fan 415 is installed on the top wall 412 of the first frame 410.

The first bottom wall 413 of the first frame 410 is formed opposite the top wall 412. An outer surface of the first bottom wall 413 of the first frame 410 is in contact with an inner surface of the first lateral wall 312 of the housing 310. In one exemplary embodiment, the first bottom wall 413 may have an outlet hole formed through the first bottom wall 413, but the present invention is not limited thereto.

The second bottom wall 414 of the first frame 410 is formed opposite the top wall 412. An outer surface of the second bottom wall 414 of the first frame 410 is in contact with an inner surface of the first lateral wall 312 of the housing 310. The second bottom wall 414 of the first frame 410 includes an outlet hole 414a through the second bottom wall 414. A first filter 416 is installed on the second bottom wall 414 of the first frame 410.

The second frame 420 is provided to protrude from the bottom surface of the first frame 410 in a downward direction of the first frame 410. In the interior space of the second frame 420, a second airflow introduction space 421 is formed.

The second airflow introduction space 421 of the second frame 420 is equipped with an inspection module 422. The inspection module 422 is disposed in the area where the waiting port 380 is provided, when the inner space is separated into an area where the treatment container 320 is provided and an area where the waiting port 380 is provided based on a line perpendicular to the direction in which the treatment container 320 and the waiting port 380 are arranged when viewed from above.

In one exemplary embodiment, the inspection module 422 is a camera for photographing the interior space of the housing 310. In one exemplary embodiment, the camera is a thermal imaging camera. Further, the inspection module 422 does not have a separate power source, but uses power provided by the airflow supply unit 400.

The second frame 420 includes an outer wall 423, a bottom wall 424, and an inner wall 425. The outer wall 423 of the second frame 420 is formed opposite the first lateral wall 312 of the housing 310. The outer wall 423 of the second frame 420 is adjacent to the first lateral wall 312 of the housing 310.

The bottom wall 424 of the second frame 420 is formed opposite the first bottom wall 413 and the second bottom wall 414 of the first frame 410. The bottom wall 424 of the second frame has an outlet hole 424a formed through the bottom wall 424. A second filter 426 is installed on the bottom wall 424 of the second frame 420.

The inner wall 425 of the second frame 420 is formed by extending from the inner side of the second bottom wall 414 of the first frame 410 to an inner side of the bottom wall 424 of the second frame 420. The inner wall 425 of the second frame 420 is provided with a downwardly inclined surface that approaches the first lateral wall 312 of the housing 310. The inner wall 425 of the second frame 420 is a wall facing the interior space of the housing 310. The inner wall 425 of the second frame 420 is configured as a window. In one exemplary embodiment, the inner wall 425 of the second frame 420 is formed of germanium glass. Thus, the inspection module 422 may photograph the interior space of the housing 310.

As described above, by integrating the first frame 410, which includes the fan 415 and the first filter 416, and the second frame 420, which includes the inspection module 422, the problem of contamination by lifting or scattering, which may be caused by installing conventional fan filter unit and inspection module separately, is avoided. In addition, wiring issues may be eliminated by not requiring a separate power connection to the inspection module 422. Additionally, by installing the second filter 426 below the inspection module 422, the cooling efficiency of the inspection module 422 may be improved.

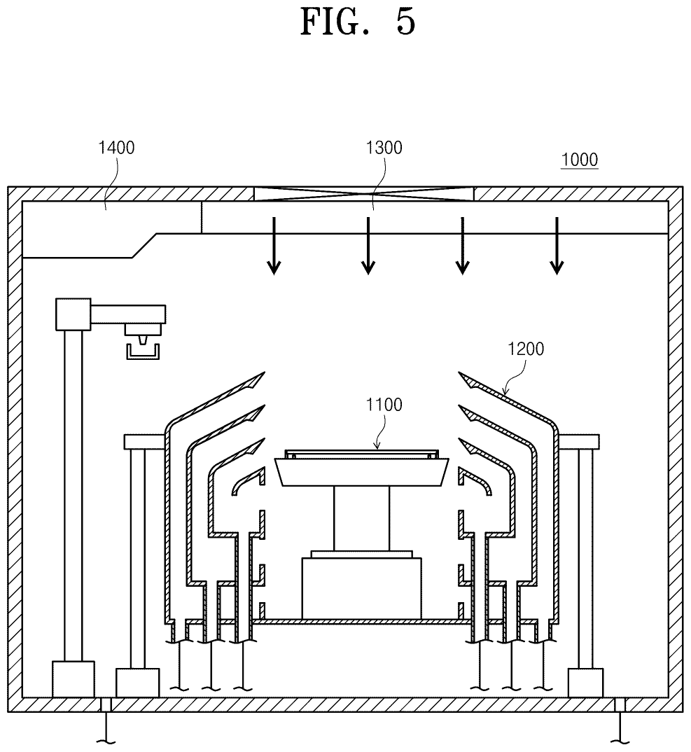

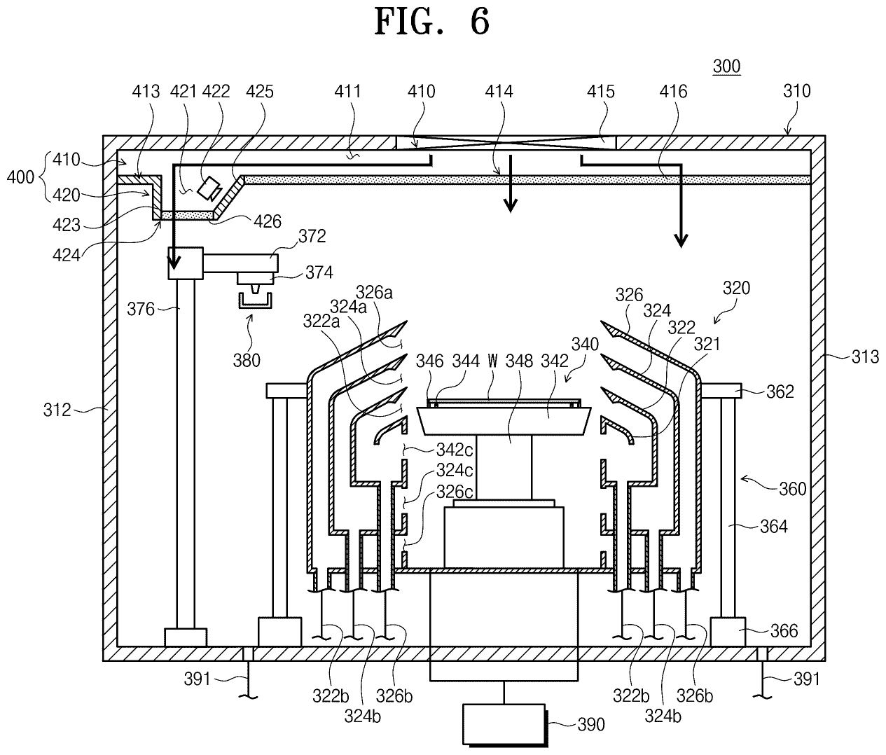

FIGS. 5 to 6 are diagrams illustrating the effect of the substrate treating apparatus according to the exemplary embodiment of the present invention.

FIG. 5 is a schematic diagram illustrating the flow of airflow in a conventional process chamber. FIG. 6 is a schematic diagram illustrating the flow of airflow in a process chamber according to an exemplary embodiment of the present invention.

Referring first to FIG. 5, in an existing process chamber 1000, gas from the outside is introduced into the chamber via a fan filter unit 1300, and no gas is introduced on the side of the photographing module 1400. This results in stagnation of airflow on one side of the inner space of the process chamber 1000. One side of the interior space is the interior space below the photographing module 1400.

Referring now to FIG. 6, in the process chamber 300 according to the exemplary embodiment of the present invention, outside gas is introduced into the first airflow introduction space 411 via the fan 415 in the first frame 410. A portion of the gas introduced into the first airflow introduction space 411 is introduced into the second airflow introduction space 421 of the second frame 420. The gas introduced into the second airflow introduction space 421 is supplied to one side of the treatment space through the second filter 426 and the outlet hole 424a in the bottom wall 424. The one side of the treatment space is the area of the treatment space where the waiting port 380 is installed.

The remaining portion of the gas introduced into the first airflow introduction space 411 is supplied to the other side of the treatment space through the first filter 416 and the outlet hole 414a of the second bottom wall 414. Thus, according to the exemplary embodiment of the present invention, the gas from the outside introduced through the fan 415 of the first frame 410 may be uniformly supplied to the interior space.

The foregoing detailed description illustrates the present invention. Furthermore, the foregoing is an illustrative description of a preferred exemplary embodiment of the present invention, and the invention is intended for use in a variety of other combinations, modifications, and environments. That is, changes or modifications are possible within the scope of the concept of the invention disclosed herein, the scope equivalent to the written disclosure, and/or within the scope of skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. An apparatus for treating a substrate, the apparatus comprising:
a housing having an interior space;
a treatment container disposed in the interior space and having a treatment space in which the substrate is treated;
a support unit for supporting the substrate in the interior space;
a nozzle unit having a nozzle for supplying a treatment liquid to the substrate supported on the support unit;
an exhaust unit for exhausting airflow in the treatment space;
an airflow supply unit for providing downdraft airflow into the interior space; and
an inspection module for inspecting the treatment space,
wherein the inspection module is installed in the airflow supply unit.

2. The apparatus claim 1, wherein the airflow supply unit includes:
a first frame having a first airflow introduction space formed therein; and
a first filter installed on a bottom wall of the first frame, and
the inspection module includes a second frame provided to protrude from a bottom surface of the first frame in a downward direction of the first frame, and having a second airflow introduction space formed therein.

3. The apparatus of claim 2, wherein the inspection module further includes a camera mounted in the second airflow introduction space and provided to photograph the treatment space.

4. The apparatus of claim 3, wherein the camera is a thermal imaging camera.

5. The apparatus of claim 4, wherein the first airflow introduction space and the second airflow introduction space are provided so that a portion of the airflow in the first airflow introduction space is introduced into the second airflow introduction space.

6. The apparatus of claim 2, wherein the second frame includes an outer wall, an inner wall, and a bottom wall,
the second airflow introduction space is defined by walls including the outer wall, the inner wall, and the bottom wall,
the inner wall is a wall facing the treatment space, and
the bottom wall has an outlet hole formed for the airflow introduced into the second airflow introduction space to flow in a downward direction.

7. The apparatus of claim 6, wherein the bottom wall is equipped with a second filter.

8. The apparatus of claim 6, wherein the inner wall is provided as a window to allow the inspection module to photograph.

9. The apparatus of claim 6, wherein the inner wall is provided with an inclined surface that approaches a lateral wall of the housing as it descends.

10. The apparatus claim 1, wherein an outer side of the treatment container in the interior space is provided with a waiting port in which the nozzle waits, and
when the interior space is separated into an area in which the treatment container is provided and an area in which the waiting port is provided based on a line perpendicular to a direction in which the treatment container and the waiting port are arranged when viewed from above, the inspection module is disposed in the area in which the waiting port is provided.

11. The apparatus of claim 2, wherein the first frame and the second frame are integrally provided.

12. The apparatus of claim 2, wherein a fan is installed on a top wall of the first frame.

13. An apparatus for treating a substrate, the apparatus comprising:
a housing having an interior space;
a first frame having a first airflow introduction space into which gas from the outside is introduced; and
a second frame positioned on a bottom wall of the first frame so as to protrude downwardly from the first frame, and having a second airflow introduction space therein,
wherein a portion of the airflow introduced into the first airflow introduction space flows through the bottom wall of the first frame into the interior space,
another portion of the airflow introduced into the first airflow introduction space flows from the first airflow introduction space to the second airflow introduction space, and then flows through a bottom wall of the second frame into the interior space, and
the second airflow introduction space is equipped with a camera.

14. The apparatus of claim 13, wherein a fan is installed on a top wall of the first frame.

15. The apparatus of claim 13, wherein the bottom wall of the first frame is mounted with a first filter.

16. The apparatus of claim 13, wherein the bottom wall of the second frame is mounted with a second filter.

17. The apparatus of claim 13, wherein the camera is a thermal imaging camera.

18. An apparatus for treating a substrate, the apparatus comprising:
a housing having an interior space;
a treatment container disposed in the interior space and having a treatment space in which the substrate is treated;
a support unit for supporting the substrate in the treatment space;
a nozzle unit having a nozzle for supplying a treatment liquid to the substrate supported on the support unit;
an exhaust unit for exhausting airflow in the treatment space;
an airflow supply unit for providing downdraft airflow into the interior space; and
an inspection module for inspecting the interior space,
wherein the airflow supply unit includes:
a first frame having a first airflow introduction space formed therein;
a first filter installed in an upper portion of the first frame; and
a first fan installed in a lower portion of the first frame, and
the inspection module includes:
a second frame installed in the first frame and having a second airflow introduction space communicating with the first airflow introduction space;
a camera provided in the second airflow introduction space; and
a second filter installed on a bottom wall of the second frame, and
airflow introduced into the second airflow introduction space flows through the second filter into the interior space.

19. The apparatus of claim 18, wherein the second frame includes an outer wall, an inner wall, and a bottom wall,
the second airflow introduction space is defined by walls including the outer wall, the inner wall, and the bottom wall,
the inner wall is a wall facing the treatment space, and
an outlet hole is formed in the bottom wall such that airflow introduced into the second airflow introduction space flows in a downward direction,
the inner wall is provided as a window to allow the camera to photograph, and
the inner wall is provided with an inclined surface that approaches a lateral wall of the housing as it descends.

20. The apparatus of claim 18, wherein an outer side of the treatment container in the interior space is provided with a waiting port in which the nozzle waits, and
when the interior space is separated into an area in which the treatment container is provided and an area in which the waiting port is provided based on a line perpendicular to a direction in which the treatment container and the waiting port are arranged when viewed from above, the inspection module is disposed in the area in which the waiting port is provided.
